(19) United States
(12) Patent Application Publication
(10) Pub. No.: US 2026/0318950 A1
(43) Pub. Date: Oct. 15, 2026

(54) PROBE DEVICE, PROTECTION METHOD FOR PROBE END OF PROBE DEVICE, PROBE SYSTEM, TESTING METHOD, AND TESTED DEVICE

(71) Applicant: MPI CORPORATION, CHU-PEI CITY (TW)

(72) Inventors: YU-HSUN HSU, CHU-PEI CITY (TW); TING-YAN HUANG, CHU-PEI CITY (TW); PO-YI TING, CHU-PEI CITY (TW)

(73) Assignee: MPI CORPORATION, CHU-PEI CITY (TW)

(21) Appl. No.: 19/645,610

(22) Filed: Apr. 13, 2026

Related U.S. Application Data
(60) Provisional application No. 63/788,142, filed on Apr. 14, 2025.

(51) Int. Cl. G01R 1/067; G01R 1/07

(52) U.S. Cl. CPC G01R 1/06738; G01R 1/06772; G01R 1/06788; G01R 1/071

(57) ABSTRACT

A probe device includes a main body, a probe having a supporting portion protruding from the main body and a probe end disposed at an end of the supporting portion, and a protective cover disposed on the main body. The protective cover is switchable between a protection position and a non-protection position while remaining connected to the main body and is selectively positionable at either position. When at the protection position, a protective portion of the protective cover shields at least one side of the probe end to block external forces approaching the probe end from at least one direction. When at the non-protection position, the protective cover is spaced away from the probe end. Accordingly, the device protects the probe end while eliminating the need for additional storage space and reducing the risk of loss of the protective cover and its associated components.

### BACKGROUND OF THE INVENTION

### 1. Field of the Invention

The present invention relates to a probe device including a radio frequency (RF) probe and/or optical probe, and more particularly to a probe device having a protective cover for protecting a probe end, a protection method for a probe end of the probe device, a probe system and a testing method employing the probe device, and a tested device.

### 2. Description of the Related Art

A probe device is a device used to test electrical characteristics of electronic components or optical characteristics of optoelectronic components. For example, a radio frequency probe may electrically contact conductive contacts of an electronic device under test to measure electrical characteristics thereof, or an optical probe (such as a fiber probe or a fiber array) may optically couple with an optical interface of the device under test to transmit and measure optical signals. In general, the probe device mainly comprises a main body and a probe disposed on the main body. The probe includes a support portion protruding from the main body and a probe end located at an end of the support portion (for example, a probe tip of a radio frequency probe or a fiber end face of an optical probe), for corresponding to a test interface of the device under test.

However, regardless of whether a radio frequency probe for electrical contact or an optical probe for optical coupling is used, the probe end generally has an extremely small size and high precision. During transportation, movement, storage, or installation of the probe device, the probe end is highly susceptible to damage or performance degradation due to accidental contact or impact by external forces. For example, a probe tip of a radio frequency probe may be deformed due to accidental contact, thereby affecting contact resistance; and an end face of an optical probe (such as a fiber end face), if contaminated or scratched, may reduce optical coupling efficiency or cause signal loss.

### SUMMARY OF THE INVENTION

The inventors of the present invention previously proposed a probe device provided with a detachable protective cover. During transportation, movement, storage, and installation of the probe device, the protective cover is mounted on the main body of the probe device to effectively protect the probe end. Before the probe device is used to test a device under test, the protective cover may be removed so that the probe end is not obstructed by the protective cover and may perform electrical contact or optical coupling operations. However, such a design still presents certain drawbacks. Since the protective cover is secured to the main body by a fastening member, such as a thumb screw, the fastening member may accidentally fall into the equipment or onto a lower portion of the apparatus equipped with the probe device during removal. In addition, after removal, an additional space is required to store the protective cover and the fastening member to prevent loss.

Accordingly, the present invention provides a probe device that includes a protective cover for protecting the probe end while avoiding the need for an additional storage space and reducing the risk of loss of the protective cover and its associated components.

The present invention provides a probe device for use in a probe system to test a device under test comprising at least one test interface. The probe device includes a main body, a probe disposed on the main body, and a protective cover. The probe comprises a support portion protruding outside the main body and extending from a front side of the main body, and a probe end disposed at an end of the support portion. The probe is one of a radio frequency probe and an optical probe, the radio frequency probe is configured to electrically contact the test interface, and the optical probe is configured to optically couple with the test interface. The protective cover is disposed on the main body and switchable relative to the main body between a protection position and a non-protection position while remaining connected to the main body, and selectively positionable at either the protection position or the non-protection position. When the protective cover is at the protection position, a protective portion of the protective cover shields at least one side of the probe end, and when the protective cover is at the non-protection position, the protective cover is spaced away from the probe end.

Accordingly, during transportation, movement, storage, and installation of the probe device, the protective cover may be positioned at the protection position to block external forces approaching the probe end from at least one direction, thereby effectively protecting the probe end and preventing accidental contact or impact damage. Before the probe device is used to test the device under test, a user may move the protective cover to the non-protection position so that the probe end is not obstructed by the protective cover and may contact the conductive contact of the device under test or optically couple with the device under test. At this time, the protective cover remains connected to the main body, and components used to connect the protective cover to the main body, such as a positioning unit described below, do not need to be detached from the main body. Accordingly, accidental dropping or loss of the protective cover or its associated components can be prevented, while the need for separate storage of the protective cover and its associated components is eliminated. As a result, the operational convenience and safety of the probe device are improved, and the testing efficiency is enhanced.

Preferably, when the probe is the radio frequency probe, the support portion is a probe beam, and the probe end is a probe tip unit fixed to the probe beam. Further, the probe tip unit extends from the probe beam away from the front side of the main body.

Preferably, the probe further comprises a coaxial line disposed in the main body. The coaxial line comprises a signal transmission path and a ground potential transmission path surrounding the signal transmission path. The coaxial line protrudes from the front side of the main body to form the probe beam. The probe tip unit comprises a signal probe tip and a ground probe tip. The signal probe tip is electrically connected with the signal transmission path, and the ground probe tip is electrically connected with the ground potential transmission path. The protective cover is disposed adjacent to the coaxial line.

Accordingly, the probe may transmit a test signal through the signal transmission path of the coaxial line and the signal probe tip of the probe tip unit, and transmit a ground potential through the ground potential transmission path of the coaxial line and the ground probe tip of the probe tip unit, such that the ground potential surrounds the test signal. This configuration achieves favorable impedance matching and is advantageous for high-frequency testing.

Preferably, the protective cover is movable in a direction consistent with an extending direction of the probe beam.

Accordingly, the probe beam protrudes from the front side of the main body and extends forward from the main body. When the protective cover moves from the non-protection position to the protection position, the protective cover also slides forward and protrudes from the main body toward the probe tip unit to a position around the probe tip unit. In other words, the moving direction of the protective cover is generally consistent with the extending direction of the exposed probe beam, such that the moving direction and the extending direction do not intersect, although they are not limited to being parallel. With such an arrangement, the protective cover only protrudes a short distance from the main body when at the protection position, and retracts behind the front side of the main body when at the non-protection position. The movement distance is therefore small and occupies little additional space, thereby improving efficiency and reducing interference.

Preferably, when the protective cover is at the protection position, a distance by which the protective cover protrudes from the front side of the main body is greater than a distance by which the probe protrudes from the front side of the main body. More preferably, when the protective cover is at the non-protection position, the protective cover does not protrude beyond the front side of the main body.

Accordingly, when the protective cover is at the protection position, the protective portion may partially surround around a lateral side of the probe end to block external forces approaching the lateral side, and may also partially extend beyond the probe end to block external forces approaching the front side of the probe end, thereby providing enhanced protection of the probe end.

Preferably, the protective cover is slidably disposed on the main body so as to move between the protection position and the non-protection position.

Accordingly, the protective cover can be conveniently and rapidly switched between the protection position and the non-protection position while remaining connected to the main body, thereby effectively enhancing operational convenience and safety of the probe device and improving testing efficiency. With the design of a slidably disposed protective cover, occupation of additional space can be avoided, and interference with other parts of the probe device (such as the cantilever portion of the probe, the main body, or cable connection interfaces mounted on the main body) or other components of the probe system (such as cables or testing machines) can likewise be prevented. Moreover, the protective cover only needs to slide a short distance to retract behind the front side of the main body. More preferably, when at the non-protection position, the protective cover does not protrude beyond the front side of the main body at all, thereby avoiding interference with other components and preventing obstruction of the testing operation.

More preferably, the main body comprises a rear side opposite to the front side, and two coaxial connecting terminals disposed on the rear side. The probe is electrically connected with the two coaxial connecting terminals. The main body further comprises a sliding groove into which the protective cover is slidably disposed, and the sliding groove is located between the two coaxial connecting terminals.

Accordingly, a rear end of the probe may be connected to two coaxial cables through the two coaxial connecting terminals, while a front end of the probe may be provided with multiple probe tips, including probe tips for transmitting test signals and probe tips for transmitting ground potential. Such a configuration achieves favorable impedance matching and is advantageous for high-frequency testing. By arranging the protective cover and the corresponding sliding groove between the two coaxial connecting terminals, space may be effectively utilized, and the protective cover only needs to slide a short distance between the protection position and the non-protection position, thereby achieving improved testing efficiency and enhanced probe tip protection.

More preferably, the main body gradually widens from the front side toward the rear side.

Accordingly, the probe tip of the probe is located in front of the front side of the main body and corresponds in position to the protective cover and the sliding groove, such that the sliding distance of the protective cover is small and the probe tip protection effect is favorable. A portion of the probe located within the main body may extend toward the two coaxial connecting terminals located on two sides of the sliding groove in accordance with the gradually widening shape of the main body, and be connected to the two coaxial connecting terminals. With such a structural configuration, the probe device may achieve the required high-frequency testing, high efficiency, operational safety, and effective probe tip protection within a minimized overall volume.

More preferably, the front side of the main body is provided with at least one receiving recess. When the protective cover is at the non-protection position, the protective portion is accommodated in the at least one receiving recess.

Accordingly, the protective portion may be formed as a structure sufficient to effectively block external forces approaching from various directions toward the probe end. Even if such a structure occupies a certain amount of space around the probe end when the protective cover is at the protection position, when the protective cover is at the non-protection position, the protective portion is accommodated within the receiving recess, and may even not protrude beyond the front side of the main body at all. Such a design effectively utilizes space and prevents the protective cover from interfering with the testing operation.

Preferably, the protective cover comprises an extension portion. The protective portion is located at one end of the extension portion, and an included angle is formed between the protective portion and the extension portion.

Accordingly, the protective portion is formed by protruding from a surface of the extension portion in a direction non-parallel to that surface, such that an included angle is formed between the protective portion and the extension portion. The included angle is preferably 90 degrees or approximately 90 degrees, that is, the protective portion is substantially perpendicular to the extension portion. With such an arrangement, when the protective cover is at the protection position, the protective portion is located around a portion of the probe end, thereby achieving protection of the probe end.

More preferably, the protective portion is located on opposite two sides of the extension portion to form a passage for accommodating the probe tip unit of the probe (RF probe). When the protective cover is at the protection position, the probe tip unit is located within the passage.

Accordingly, when the protective cover is at the protection position, at least two sides of the probe tip are protected by the protective portion of the protective cover, and at least another side is protected by the extension portion. Such a protective cover provides enhanced probe tip protection.

More preferably, the extension portion comprises an upper surface. The probe is located above the upper surface of the extension portion. The protective portion comprises two guard plates protruding from the upper surface, and the passage is formed between the two guard plates.

Accordingly, the extension portion of the protective cover is located below the probe, while the two guard plates of the protective portion are respectively located at left and right sides of the probe. The extension portion and the two guard plates together form a U-shaped structure, and the passage is formed therebetween. When the protective cover is at the protection position, the protective cover can effectively block external forces approaching from various directions toward the probe tip, thereby providing enhanced probe tip protection.

More preferably, the main body comprises a sliding groove into which the extension portion is slidably disposed. The protective portion extends from the extension portion toward the probe tip unit of the probe to form the passage through which the probe passes.

Accordingly, the extension portion of the protective cover may be located only on one side of the probe (for example, below the probe), or on two opposite sides of the probe (for example, above and below the probe), while the protective portion is located on other sides (for example, at left and right sides of the probe). When the protective cover is at the protection position, the extension portion may also provide probe tip protection on the side where it is located, while the protective portion provides probe tip protection on other sides. Such a protective cover not only achieves favorable protection performance, but also enables a simplified sliding structure and reduced space occupation.

More preferably, the main body comprises an elongated slot. The probe device further comprises a positioning unit disposed in the elongated slot and operable by a user to switch between a positioned state and a non-positioned state. The positioning unit is connected with the protective cover. When the positioning unit is in the non-positioned state, the positioning unit is slidable along the elongated slot to thereby drive the protective cover to slide. When the positioning unit is in the positioned state, the positioning unit is restricted and positioned within the elongated slot to thereby position the protective cover.

Accordingly, the positioning unit facilitates a user in sliding the protective cover to the protection position or to the non-protection position, thereby enabling convenient operation of the probe device and improving testing efficiency.

Alternatively, the probe device of the present invention may be designed in such a way that the protective cover is rotatably disposed on the main body. When the protective cover switches between the protection position and the non-protection position, the protective cover rotates relative to the main body.

Accordingly, the protective cover may be switched between the protection position and the non-protection position while remaining connected to the main body, thereby effectively enhancing operational convenience and safety of the probe device and improving testing efficiency.

In one embodiment of the present invention, the main body comprises a protective cover mounting surface. When the protective cover rotates away from the protection position, the protective cover moves in a direction in which the protective cover mounting surface faces.

Accordingly, when the protective cover is at the protection position, the protective cover extends along the protective cover mounting surface on one side of the probe (for example, below the probe) and extends to a position around the probe end to provide probe end protection. When rotating away from the protection position, the protective cover moves in the direction in which the protective cover mounting surface faces (for example, rotating downward from a position below the probe). Although such movement may require additional space, the structure may still be designed to facilitate operation and avoid interference, thereby enhancing operational convenience and safety of the probe device and improving testing efficiency.

Alternatively, in another embodiment of the present invention, the main body comprises at least one protective cover mounting surface. When the protective cover switches between the protection position and the non-protection position, the protective cover rotates about a rotation axis perpendicular to the at least one protective cover mounting surface.

Accordingly, when the protective cover is at the protection position, the protective cover extends along the at least one protective cover mounting surface on at least one side of the probe (for example, above and/or below the probe) and extends to a position around the probe end to provide probe end protection. When rotating away from the protection position, the protective cover rotates in a direction substantially parallel to the at least one protective cover mounting surface and partially moves away from the at least one protective cover mounting surface, such that the protective portion moves away from around the probe end. Although such movement may require additional space, the structure may still be designed to facilitate operation and avoid interference, thereby enhancing operational convenience and safety of the probe device and improving testing efficiency.

Preferably, when the probe is the optical probe, the probe comprises at least one optical fiber, the at least one optical fiber is disposed in the main body and extends and is fixed to the support portion, and the probe end is an optical coupling surface formed by the at least one optical fiber protruding outward from an end of the support portion.

Preferably, when the probe is the optical probe, the probe comprises an optical fiber ribbon. The optical fiber ribbon is disposed in the main body and comprises a plurality of optical fibers arranged in parallel. The plurality of optical fibers are disposed in the support portion. The plurality of optical fibers and the support portion collectively form a fiber array unit, and ends of the plurality of optical fibers collectively define an optical coupling surface.

Accordingly, when the probe is configured as the optical probe, the optical fiber ribbon disposed in the support portion provides a stable optical path, and the optical fiber ribbon is fixed by the support portion such that an optical coupling surface (the probe end) can achieve high-precision optical alignment with the test interface of the device under test. Further, when the optical fiber ribbon and the support portion collectively form a fiber array unit (FAU), the support portion structurally integrates and positions the plurality of optical fibers arranged in parallel, enabling the probe device to perform parallel testing corresponding to a plurality of optical paths, thereby achieving high-efficiency optical testing operations.

Preferably, the protective cover comprises an extension portion, and the protective portion comprises at least one guard plate protruding from a surface of the extension portion facing toward the support portion, and the at least one guard plate is configured to correspond to a shape of the support portion.

Accordingly, by virtue of the configuration in which the protective cover includes the guard plates protruding from the extension portion and corresponding to a shape of the support portion, when the protective cover is at the protection position, the optical coupling surface (the probe end) is accommodated within a space defined by the guard plates. Such an enclosing structure can effectively prevent the optical coupling surface from being damaged, displaced, or contaminated by environmental dust, thereby achieving protection of the optical coupling surface of the optical probe.

Preferably, the main body comprises a first arm and a second arm, the support portion is connected to the first arm, and the protective cover is pivotally connected at a junction of the first arm and the second arm or at a position adjacent to the junction. The protective cover, the first arm, and the second arm are configured such that the protective cover is selectively positionable at the protection position and the non-protection position by at least one magnetic element.

Accordingly, the protective cover is rotatable within a space defined by the first arm and the second arm so as to switch between the protection position and the non-protection position, thereby effectively utilizing a space of the main body and avoiding interference with testing operations. In addition, by means of magnetic attraction, the protective cover can be stably positioned at the protection position or the non-protection position in a structurally simple manner, thereby improving operational convenience.

Preferably, the protective cover is at least partially transparent, thereby allowing a user to observe the condition of the probe tip without moving the protective cover to the non-protection position.

Preferably, the protective cover is at least partially made of a heat-insulating material to reduce thermal influence on the probe caused by operation of the probe system, or made of an electromagnetic shielding material to isolate signal interference.

The present invention further provides a protection method for a probe end of a probe device, applied to the probe device that is used in a probe system to test a device under test comprising at least one test interface. The probe tip protection method comprises:
providing a main body disposed with a probe comprising a support portion protruding outside the main body and extending from a front side of the main body, and a probe end disposed at an end of the support portion, wherein the probe is one of a radio frequency probe and an optical probe;
disposing a protective cover on the main body such that the protective cover is switchable relative to the main body between a protection position and a non-protection position while remaining connected to the main body, and selectively positionable at either the protection position or the non-protection position;
wherein, when the protective cover is moved to the protection position, a protective portion of the protective cover shields at least one side of the probe end to protect the probe end; and
when the protective cover is moved to the non-protection position, the protective cover moves away from the probe end, thereby enabling the probe end of the radio frequency probe to electrically contact the test interface of the device under test, or enabling the probe end of the optical probe to optically couple with the test interface.

Accordingly, when the probe is not in use, that is, when no testing is being performed, positioning the protective cover at the protection position effectively protects the probe end and prevents accidental contact or collision that may cause damage. When the probe is to be used for testing, the protective cover may be moved to the non-protection position. At this time, the protective cover remains connected to the main body, thereby preventing accidental dropping or loss of the protective cover or its associated components, and eliminating the need of storage space for accommodating the protective cover and its associated components. This enhances operational convenience and safety of the probe device and improves testing efficiency.

The present invention further provides a probe system for testing a device under test formed on a substrate. The probe system comprises a probe device as described above, a probing station, and a signal measurement module. The probing station comprises a chuck for supporting the substrate. The signal measurement module is electrically connected with the probe of the probe device for transmitting signals to the device under test or receiving signals from the device under test through the probe device.

Accordingly, since the probe system employs the probe device described above, the probe system achieves the aforementioned advantages of the probe device, effectively protects the probe end, and avoids the need for additional storage space and the risk of loss of the protective cover and its associated components, thereby enhancing operational convenience and safety and improving testing efficiency.

The present invention further provides a testing method for testing a device under test. The testing method comprises:
providing the probe system as described above;
positioning the probe device at a position aiming at the device under test; and
bringing the probe end of the radio frequency probe of the probe device into contact with the device under test and detecting an electric characteristic of the device under test; or
bringing the probe end of the optical probe of the probe device into optical coupling with the device under test and detecting an optical characteristic of the device under test.

The present invention further provides a tested device, which is a device tested by the method described above.

Accordingly, since the testing method employs the probe device described above, the aforementioned advantages of the probe device may be achieved, including effective probe end protection, avoidance of additional storage space and loss of the protective cover and its associated components, and enhancement of operational convenience, safety, and testing efficiency.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

FIG. 1 is a schematic side view of a probe system provided in accordance with a first preferred embodiment of the present invention.

FIG. 2 is a perspective assembled view of a radio frequency probe device of the probe system provided in the first preferred embodiment of the present invention, showing a protective cover of the radio frequency probe device located at a protection position.

FIG. 3 is similar to FIG. 2, except that the protective cover is located at a non-protection position.

FIG. 4 is another perspective assembled view of the radio frequency probe device, showing the protective cover located at the protection position.

FIG. 5 is similar to FIG. 4, except that the protective cover is located at the non-protection position.

FIG. 6 is an exploded perspective view of the radio frequency probe device.

FIG. 7 is a top view of the radio frequency probe device, showing the protective cover located at the protection position.

FIG. 8 is similar to FIG. 7, except that the protective cover is located at the non-protection position.

FIG. 9 is a sectional view taken along line 9-9 of FIG. 7, showing a positioning unit of the radio frequency probe device in a positioned state.

FIG. 10 is similar to FIG. 9, except that the positioning unit is in a non-positioned state.

FIG. 11 is similar to FIG. 9, except that the protective cover is located at the non-protection position.

FIGS. 12A to 12C are schematic side views of a radio frequency probe device provided in accordance with a second preferred embodiment of the present invention, showing states in which a protective cover of the radio frequency probe device is switched from a protection position to a non-protection position.

FIGS. 13 to 15 are respectively a schematic perspective view, a schematic side view, and a schematic top view of a radio frequency probe device provided in accordance with a third preferred embodiment of the present invention, showing a protective cover of the radio frequency probe device located at a protection position.

FIG. 16 is similar to FIG. 15, except that the protective cover is located at a non-protection position.

FIG. 17 is a schematic side view of a radio frequency probe device provided in accordance with a fourth preferred embodiment of the present invention, showing a protective cover of the radio frequency probe device located at a protection position.

FIG. 18 is a schematic view of a probe beam and a probe tip unit of the radio frequency probe device of the present invention.

FIG. 19 is a sectional view taken along line 19-19 of FIG. 7.

FIGS. 20A and 20B are perspective schematic views of an optical probe device provided in accordance with a fifth preferred embodiment of the present invention, illustrating a process in which a protective cover of the optical probe device is switched from a protection position to a non-protection position.

FIG. 20C is a side view of the optical probe device shown in FIG. 20B.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

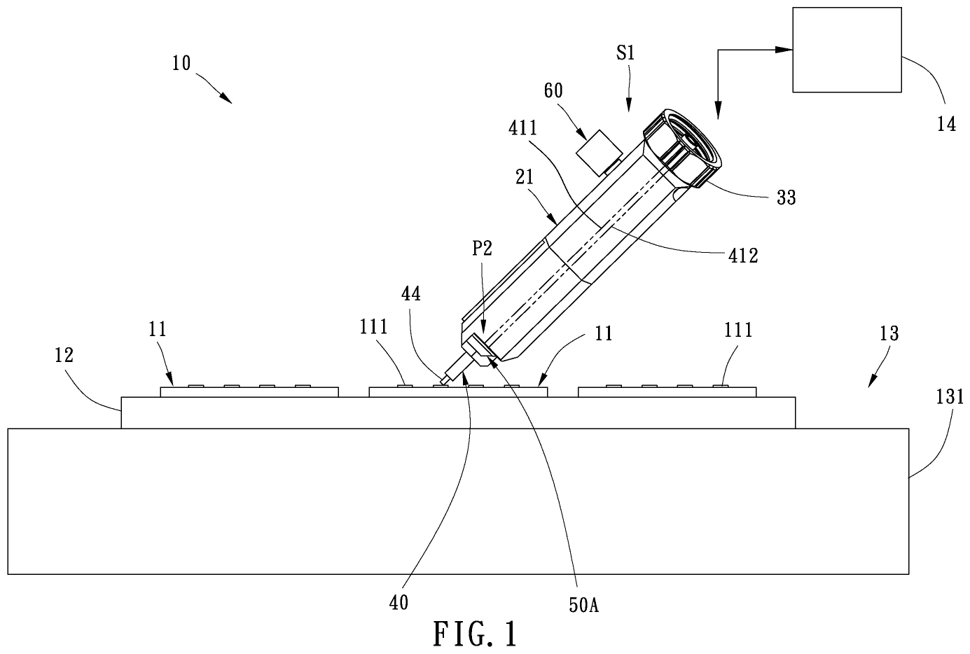

Referring first to FIG. 1, a probe system 10 provided in accordance with a first preferred embodiment of the present invention comprises a probe device for testing a device under test. The probe device disclosed herein may be a radio frequency probe device or an optical probe device. In this embodiment, the probe device is exemplified as a radio frequency probe device 21, and the probe system 10 is adapted to test an electronic device under test 11. The electronic device under test 11 is formed on a substrate 12 (for example, a semiconductor wafer), and the electronic device under test 11 comprises at least one test interface including one or more conductive contacts 111. The probe system 10 comprises a probing station 13, and the probing station 13 includes a chuck 131 for supporting the substrate 12. The probe system 10 further comprises a signal measurement module 14. The signal measurement module 14 is adapted to perform electrical testing on the electronic device under test 11 through the radio frequency probe device 21. According to testing requirements, the probe system 10 may also be configured with a plurality of radio frequency probe devices 21.

The so-called “radio frequency probe device” used herein is directed to a device comprising at least one signal transmission path, and in most cases further comprising a grounding structure, although in some cases a grounding structure may not be provided. The signal transmission path extends between a probe tip and a connecting terminal and supports propagation of electromagnetic signals within a radio frequency (RF) range. The grounding structure is configured to maintain a target impedance relative to the signal transmission path. In addition, the radio frequency probe device comprises a main body that mechanically supports the signal transmission path and the grounding structure and enables the radio frequency probe device to be connected with a system, thereby achieving mechanical contact with the device under test.

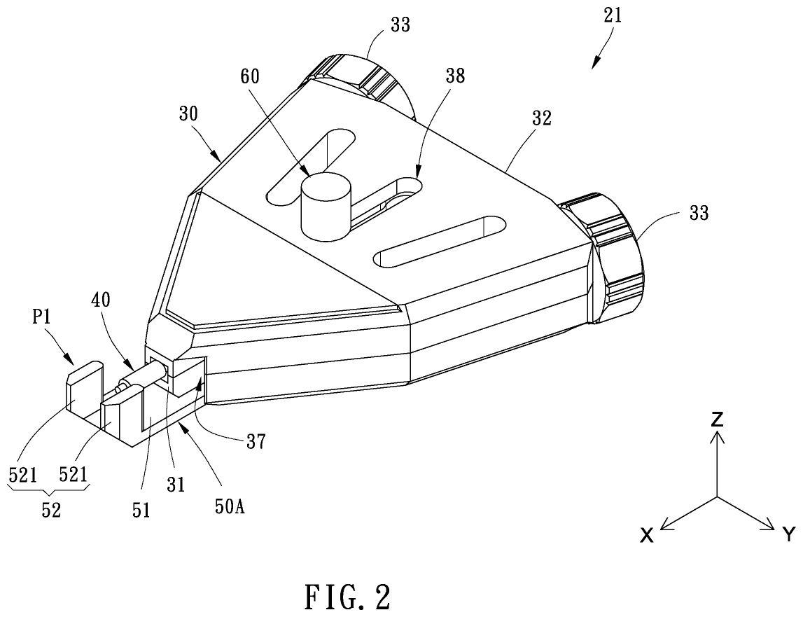

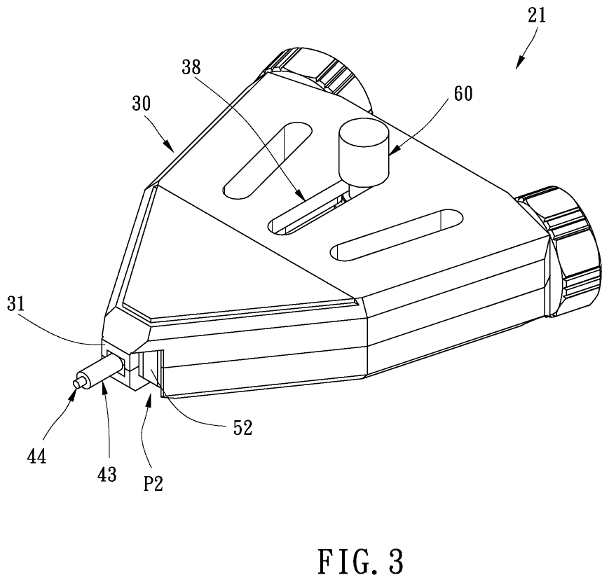

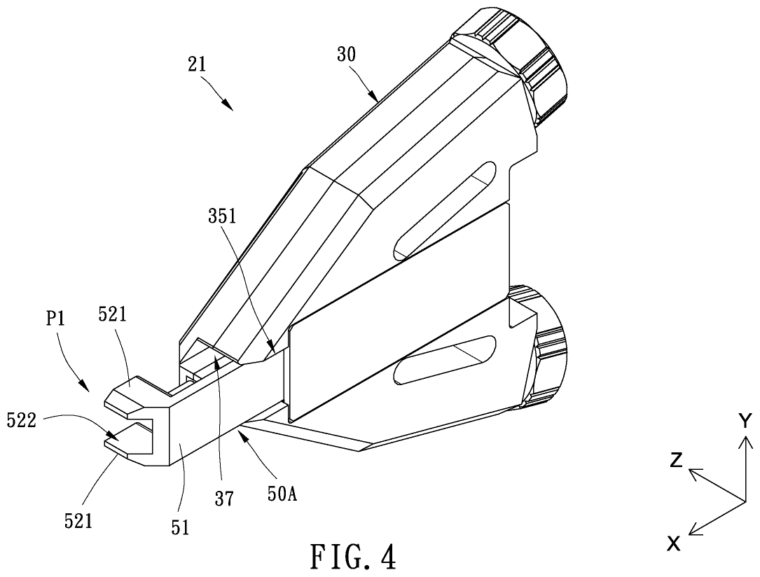

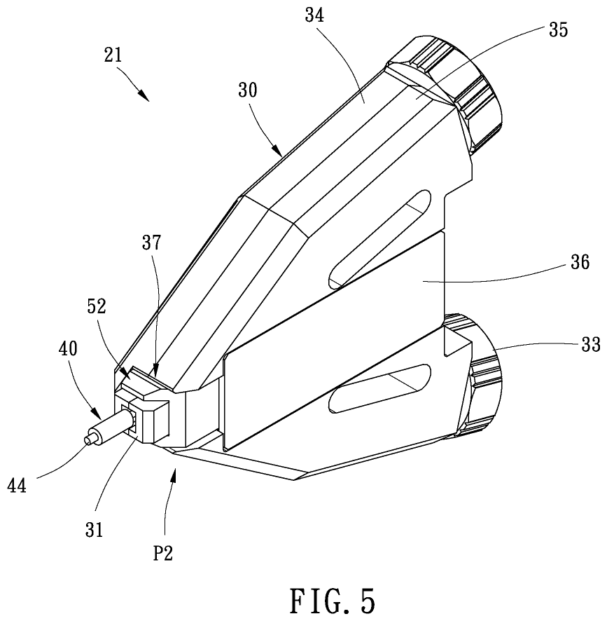

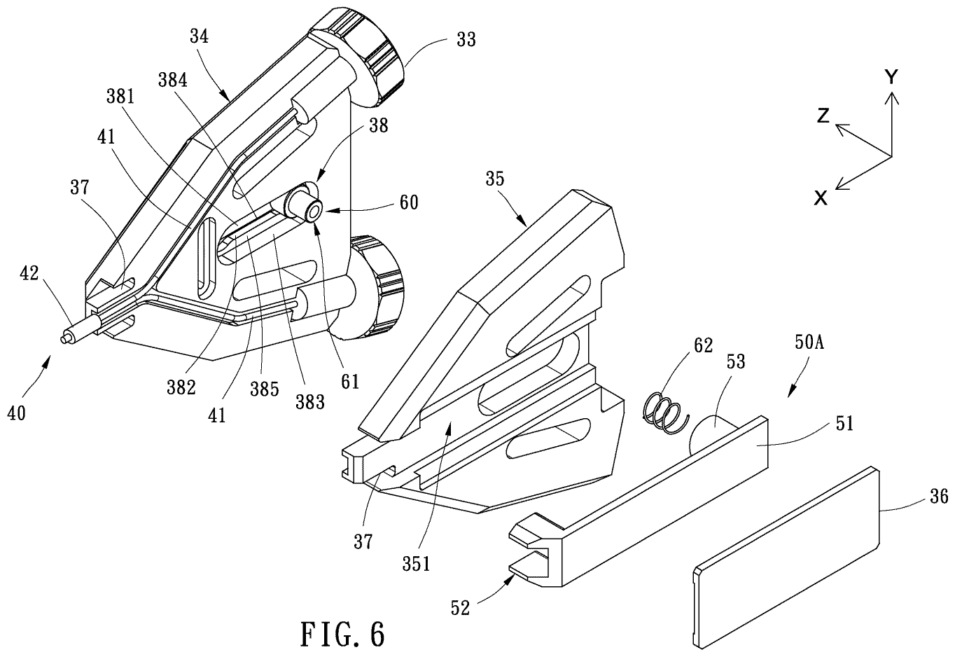

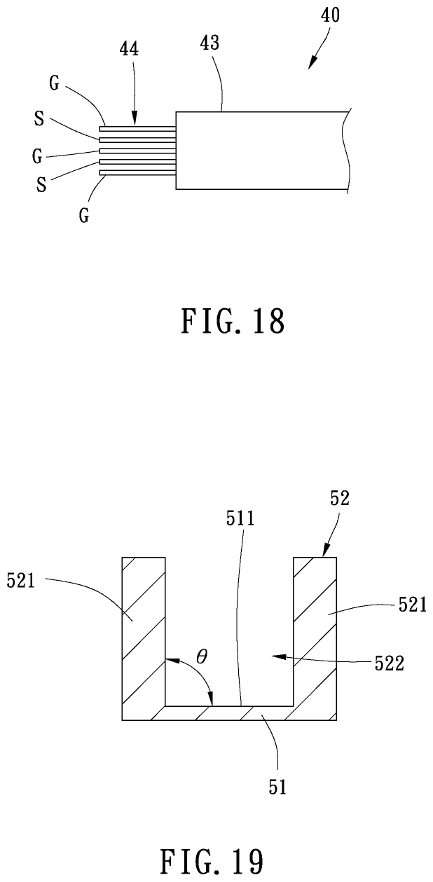

Referring to FIGS. 2 to 6, the radio frequency probe device 21 comprises a main body 30 and a probe 40 disposed on the main body 30. Correspondingly, the probe 40 in this embodiment is a radio frequency probe. The radio frequency probe device 21 defines mutually perpendicular first, second, and third axial directions (an X-axis, a Y-axis, and a Z-axis). The main body 30 has a front side 31 and a rear side 32 respectively facing positive and negative directions of the X-axis. The main body 30 gradually widens from the front side 31 toward the rear side 32, that is, a width in the Y-axis direction gradually increases. In this embodiment, the probe 40 comprises two coaxial lines 41 (as shown in FIG. 6). Most portions of the two coaxial lines 41 are disposed within the main body 30, while a portion of each coaxial line protrudes from the front side 31 of the main body 30 and passes through a barrel 42, such that the probe 40 forms a support portion, namely a probe beam 43, protruding from the front side 31 of the main body 30, as shown in FIG. 3. The probe 40 in this embodiment further comprises a probe end, namely a probe tip unit 44 of the radio frequency probe, disposed at an end of the support portion (probe beam 43). The probe tip unit 44 is fixed at an end of the probe beam 43 and extends away from the front side 31 of the main body 30. The probe tip unit 44 forms five fine probe tips arranged in a GSGSG sequence, as shown in FIG. 18, wherein “G” represents a ground probe tip configured to transmit ground potential, and “S” represents a signal probe tip configured to transmit a test signal. The ground probe tips G and the signal probe tips S are electrically connected to outer conductors and core conductors, respectively, of the two coaxial lines 41. Such a configuration is merely one example of probe tip arrangement. In practice, the number and arrangement of probe tips may be configured according to testing requirements. Because the probe tips are extremely small in size, and for the sake of simplifying the drawings and facilitating illustration, most drawings of the present invention do not depict individual probe tips in detail. Instead, a cylindrical body schematically represents the probe tip unit 44, and the ground probe tips G and signal probe tips S are schematically illustrated in FIG. 18.

From the foregoing description, it can be understood that the coaxial line 41 of the present invention comprises a signal transmission path 411 and a ground potential transmission path 412 surrounding around the signal transmission path 411, as shown in FIG. 1. The signal transmission path 411 is formed by the aforementioned core conductor, and the ground potential transmission path 412 is formed by the aforementioned outer conductor. For the sake of simplifying the drawings and facilitating illustration, the signal transmission path 411 and the ground potential transmission path 412 are schematically indicated by imaginary lines only in FIG. 1. The signal probe tips S are electrically connected to the signal transmission path 411 to jointly transmit test signals, and the ground probe tips G are electrically connected to the ground potential transmission path 412 to jointly transmit ground potential. Such a configuration enables the ground potential to surround around the test signal, thereby achieving favorable impedance matching and facilitating high-frequency testing. The coaxial line 41 of the present invention may be a wire-type coaxial line, such as a dual-layer coaxial line comprising an inner conductor, an outer conductor, and a dielectric layer disposed therebetween. In this embodiment, the coaxial line 41 is of this type. Alternatively, the coaxial line 41 of the present invention may be a coaxial structure disposed in a substrate or board, for example, comprising a signal conductor layer formed within or on a surface of the board, a ground conductor layer arranged to surround around or correspond to the signal conductor layer, and a dielectric material disposed therebetween, collectively forming a transmission structure having coaxial characteristics for transmitting high-frequency signals.

As shown in FIG. 1, the probe tip unit 44 of the probe 40 protrudes outside the main body 30. The probe tips included in the probe tip unit 44 are adapted to electrically contact the conductive contacts 111 of the test interface of the electronic device under test 11. The rear side 32 of the main body 30 is provided with two coaxial connecting terminals 33, and the two coaxial lines 41 described above are respectively electrically connected to the two coaxial connecting terminals 33, as shown in FIG. 6. By connecting coaxial cables (not shown) between the signal measurement module 14 and the two coaxial connecting terminals 33, the signal measurement module 14 may be electrically connected with the probe 40 of the radio frequency probe device 21. During testing, the radio frequency probe device 21 is positioned in a place corresponding to and aiming at the electronic device under test 11, and the probe tips of the probe 40 are brought into contact with the conductive contacts 111 of the electronic device under test 11, such that the signal measurement module 14 may then transmit high-frequency signals to the electronic device under test 11 through the radio frequency probe device 21, or receive high-frequency signals from the electronic device under test 11, thereby detecting an electric characteristic of the electronic device under test 11.

In this embodiment, the radio frequency probe device 21 further comprises a retractable protective cover 50A. The protective cover 50A is disposed on the main body 30 and is linearly slidable relative to the main body 30 between a protection position P1 and a non-protection position P2 while remaining connected to the main body 30. The protective cover 50A is selectively positionable at either the protection position P1 or the non-protection position P2. In this embodiment, the protective cover 50A is disposed adjacent to the coaxial lines 41. More specifically, a primary structural portion of the protective cover 50A (for example, an extension portion 51 described below) may be disposed adjacent to a plane along which the coaxial lines 41 are distributed (for example, a bottom surface of an upper member 34 described below), and preferably may be substantially parallel thereto.

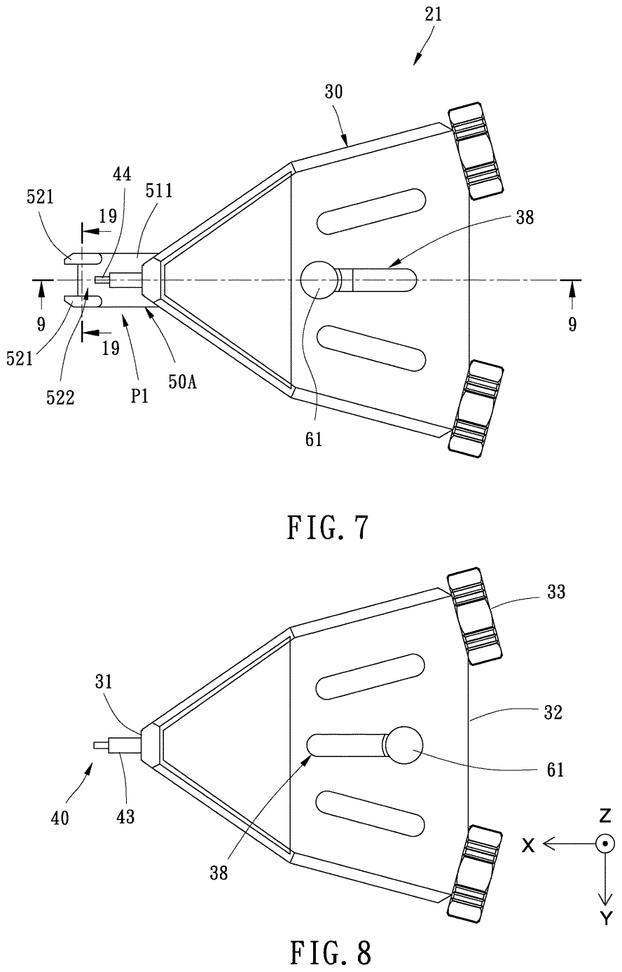

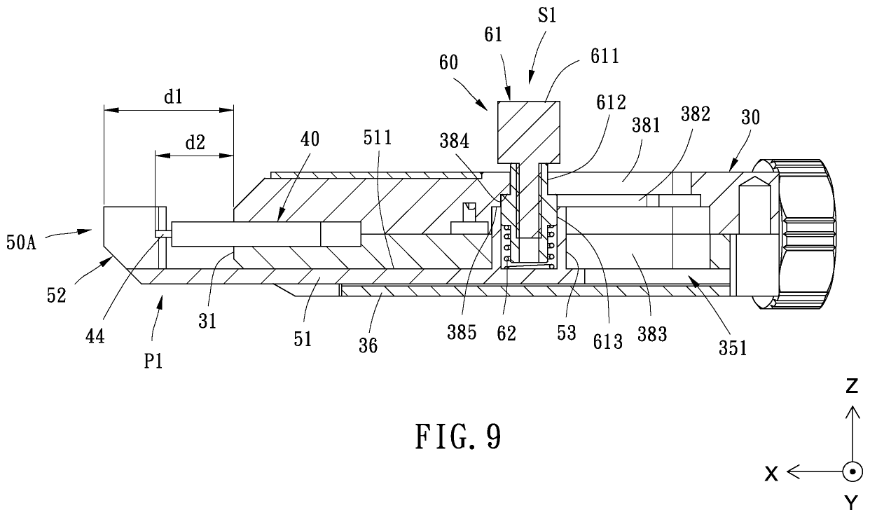

As shown in FIG. 6, the main body 30 comprises an upper member 34 and a lower member 35 secured to each other by screws, and a bottom cover 36 secured to a bottom portion of the lower member 35 by screws. The probe 40 is disposed between the upper member 34 and the lower member 35. The bottom portion of the lower member 35 is provided with a sliding groove 351 extending along the X-axis in an elongated slot shape. The sliding groove 351 is located between the two coaxial connecting terminals 33. After assembly of the upper member 34 and the lower member 35, two receiving recesses 37 are jointly formed at the front side of the main body 30. The two receiving recesses 37 are respectively located at left and right sides of the probe 40 and communicate with the sliding groove 351. Referring to FIGS. 7 to 9, the main body 30 further comprises an elongated slot 38 extending through the upper member 34 and the lower member 35 and communicating with the sliding groove 351. The elongated slot 38 comprises a first limiting portion 381, a second limiting portion 382, and a third limiting portion 383 sequentially connected along the Z-axis from top to bottom (as shown in FIGS. 6 and 9). The second limiting portion 382 has a length (along the X-axis) and a width (along the Y-axis) both greater than those of the first limiting portion 381, thereby forming a stop step 384 between the first limiting portion 381 and the second limiting portion 382. The third limiting portion 383 has a length (along the X-axis) and a width (along the Y-axis) both greater than those of the second limiting portion 382, thereby forming another stop step 385 between the second limiting portion 382 and the third limiting portion 383.

The protective cover 50A comprises an elongated plate-shaped extension portion 51, a protective portion 52 integrally connected to a front end of the extension portion 51, and an accommodating portion 53 integrally connected to the extension portion 51 and located adjacent to a rear end of the extension portion 51. As shown in FIG. 19, an included angle θ is formed between the protective portion 52 and the extension portion 51. In this embodiment, the accommodating portion 53 is a hollow cylindrical structure protruding from an upper surface 511 of the extension portion 51. The protective portion 52 is formed as a structure protruding from the upper surface 511 of the extension portion 51, such that the included angle θ is defined between the protective portion 52 and the upper surface 511 of the extension portion 51. In this embodiment, the included angle θ is 90 degrees or approximately 90 degrees, such that the protective portion 52 is substantially perpendicular to the extension portion 51. In another embodiment, the included angle θ may be greater than or less than 90 degrees, provided that, when the protective cover 50A is located at the protection position P1, the protective portion 52 shields at least one side of the probe tip unit 44 to achieve a protective effect for the probe tip unit 44. More specifically, the protective portion 52 extends from the extension portion 51 toward the probe tip unit 44 to form a passage 522. That is, when the protective cover 50A is located at the protection position P1, the protective portion 52 extends from the extension portion 51 in a direction toward the probe tip unit 44. This does not necessarily mean that the protective portion 52 extends directly facing the probe tip unit 44, but rather extends in a direction in which the probe tip unit 44 is located. For example, in this embodiment, the probe tip unit 44 is located above the extension portion 51, and the protective portion 52 extends upwardly from the extension portion 51. Alternatively, the protective portion 52 may extend both forwardly and upwardly from the extension portion 51. In this embodiment, the passage 522 allows the probe 40 to pass therethrough. Preferably, when the protective cover 50A is at the protection position P1, at least a portion of the probe tip unit 44 (for example, the probe tip) is accommodated within the passage 522. In this embodiment, the protective portion 52 comprises two guard plates 521 protruding from the upper surface 511. The two receiving recesses 37 described above are designed to respectively receive the two guard plates 521. However, the protective portion 52 of the protective cover 50A is not limited to the structure provided in this embodiment. Accordingly, the number of receiving recesses 37 at the front side of the main body 30 is not limited to two. The extension portion 51 is slidably disposed within the sliding groove 351 of the main body 30 and is retained within the sliding groove 351 by the bottom cover 36. The accommodating portion 53 is slidably disposed within the third limiting portion 383 of the elongated slot 38 of the main body 30 and abuts against the stop step 385 (as shown in FIG. 9). The sliding groove 351 and the extension portion 51 are located at at least one side of the probe 40. In this embodiment, the at least one side is a bottom side. That is, the sliding groove 351 and the extension portion 51 are located below the probe 40, and the probe 40 is located above the upper surface 511 of the extension portion 51. However, the invention is not limited thereto. For example, the sliding groove 351 and the extension portion 51 may be located at a left side and/or a right side of the probe 40. The protective portion 52 is located at at least another side of the probe 40. In this embodiment, the at least another side includes the left side and the right side. That is, the two guard plates 521 of the protective portion 52 are respectively located at the left and right sides of the probe 40, and the passage 522 is formed between the two guard plates 521. When the protective cover 50A is at the protection position P1, at least a portion of the probe tip unit 44 is located between the two guard plates 521. However, the invention is not limited thereto. For example, the protective portion 52 may include only one guard plate, or may include three guard plates connected in an inverted U-shape configuration.

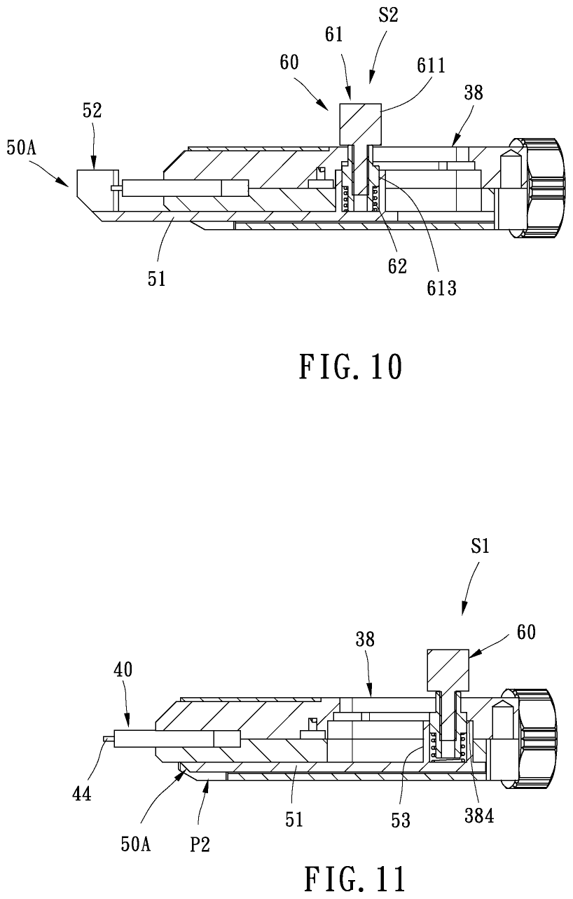

In this embodiment, the radio frequency probe device 21 further comprises a positioning unit 60. The positioning unit 60 comprises a button 61 and a resilient member 62. The resilient member 62 is a compression spring disposed within the accommodating portion 53 of the protective cover 50A. The button 61 comprises a pressing portion 611 located outside the main body 30, a body portion 612 extending through the first limiting portion 381 of the elongated slot 38, and a stop block 613 protruding outwardly from the body portion 612. The stop block 613 is partially disposed within the accommodating portion 53 of the protective cover 50A and partially located within the second limiting portion 382 of the elongated slot 38. The resilient member 62 has two opposite ends respectively abutted against a bottom surface of the stop block 613 of the button 61 and an inner surface of the accommodating portion 53 of the protective cover 50A, such that the stop block 613 is urged by the elastic force of the resilient member 62 into abutment with the stop step 384. That is, when the positioning unit 60 is not subjected to an external force, the button 61 and the protective cover 50A are positioned under the elastic force of the resilient member 62. At this time, the positioning unit 60 is in a positioned state S1, as shown in FIG. 9. When a user presses the button 61 against the elastic force of the resilient member 62, the stop block 613 separates from the stop step 384. At this time, the positioning unit 60 is in a non-positioned state S2, as shown in FIG. 10. In this condition, the user may slide the button 61 along the elongated slot 38, thereby driving the protective cover 50A to linearly slide. When the protective cover 50A is moved to a desired position, the user only needs to release the button 61, thereby allowing the positioning unit 60 to return to the positioned state S1 and position the protective cover 50A at the desired position. In other words, the positioning unit 60 is operable by a user to switch between the positioned state S1 and the non-positioned state S2. When the positioning unit 60 is in the non-positioned state S2, it is slidable along the elongated slot 38 to thereby drive the protective cover 50A to slide along the sliding groove 351. When the positioning unit 60 is in the positioned state S1, it is restricted and positioned within the elongated slot 38 to thereby position the protective cover 50A. Such an operation is simple and rapid, thereby improving testing efficiency. Furthermore, by virtue of the structural configuration including the elongated slot 38, the accommodating portion 53, and the positioning unit 60, the internal space of the main body 30 may be effectively utilized. The protective cover 50A may be rapidly moved between the protection position P1 and the non-protection position P2, and may be reliably positioned at either the protection position P1 or the non-protection position P2.

As shown in FIGS. 7 and 9, when the positioning unit 60 is located at a front end of the elongated slot 38, the protective cover 50A is located at the protection position P1. As shown in FIGS. 8 and 11, when the positioning unit 60 is located at a rear end of the elongated slot 38, the protective cover 50A is located at the non-protection position P2. When the protective cover 50A moves from the non-protection position P2 toward the protection position P1, the protective cover 50A slides in a direction in which the front side 31 of the main body 30 faces (i.e., forwardly, which in this embodiment corresponds to the positive X-axis direction), thereby gradually protruding outward from the front side 31 of the main body 30. Conversely, when the protective cover 50A moves from the protection position P1 toward the non-protection position P2, the protective cover 50A slides backwardly to move away from the probe tip unit 44, thereby gradually retracting into the interior of the main body 30. In other words, the moving direction of the protective cover 50A is consistent with an extending direction of the probe beam 43 protruding from the front side 31 of the main body 30. More specifically, the term “consistent with the extending direction” as used herein means that the moving direction of the protective cover 50A and the extending direction of the probe beam 43 are generally aligned in overall tendency. That is, the two directions share a common principal component or projection direction, and do not necessarily have to be geometrically perfectly parallel or coincident. For example, the term encompasses, but is not limited to, configurations in which the directions are parallel, approximately parallel, oriented in the same general direction, have the same axial component, or present the same directional projection on at least one plane. In other words, as long as the moving direction of the protective cover 50A generally follows the axial direction in which the probe beam 43 extends, even if there exist slight angular deviations, curvature, stepped structures, or manufacturing tolerances in the actual structure, such configurations shall still be regarded as falling within the scope of “consistent with the extending direction” as recited in the present invention.

Further, when the protective cover 50A is located at the protection position P1, the protective portion 52 shields at least one side of the probe tip unit 44 of the probe 40 and is capable of blocking external forces approaching the probe tip unit 44 from at least one direction. For example, in this embodiment, a protruding distance d1 by which the protective cover 50A extends outward from the front side 31 of the main body 30 is greater than a protruding distance d2 by which the probe 40 extends outward from the front side 31 of the main body 30, as shown in FIG. 9. Accordingly, the protective portion 52 can block external forces approaching a front side of the probe tip unit 44. In addition, the probe tip unit 44 is located within the passage 522 formed between the two guard plates 521 of the protective portion 52. Therefore, the protective portion 52 can block external forces approaching the left and right sides of the probe tip unit 44, and may even block external forces from above the probe tip unit 44. When the protective cover 50A is located at the non-protection position P2, the protective cover 50A is moved away from the probe tip unit 44 of the probe 40. The protective portion 52 is accommodated within the receiving recesses 37 at the front side 31 of the main body 30, and the protective cover 50A does not protrude beyond the front side 31 of the main body 30.

Accordingly, during transportation, movement, storage, and installation of the radio frequency probe device 21, the protective cover 50A may be positioned at the protection position P1. In this manner, the probe tip unit 44 can be effectively protected to prevent accidental contact or collision that may cause damage to the probe tips. When the radio frequency probe device 21 is to be used for testing the electronic device under test 11, a user may move the protective cover 50A to the non-protection position P2, such that the probe tips are not obstructed by the protective cover 50A and may contact the conductive contacts 111 of the electronic device under test 11. During movement of the protective cover 50A between the protection position P1 and the non-protection position P2, both the protective cover 50A and the positioning unit 60 remain connected to the main body 30 and do not need to be detached from the main body 30. Therefore, risks of components accidentally falling into the interior of the probing machine are avoided, and there is no need to separately store the protective cover 50A and the positioning unit 60. This not only prevents loss of the protective cover 50A or the positioning unit 60, but also improves operational convenience. Furthermore, switching of the protective cover 50A between the protection position P1 and the non-protection position P2 is simple and rapid, thereby saving time and labor and improving testing efficiency. In addition, since the protective cover 50A and the positioning unit 60 remain connected to the main body 30, accidental detachment during testing can be avoided, thereby reducing risks of testing errors or equipment damage caused by improper operation or loss of the protective cover.

In addition, the protective cover 50A may be at least partially transparent. For example, it may be made of acrylic material, thereby allowing a user to observe the condition of the probe tips without moving the protective cover 50A to the non-protection position P2. Alternatively, the protective cover 50A may be at least partially made of a heat-insulating material, such as a metal having a relatively low thermal conductivity, thereby reducing thermal influence on the probe 40 caused by operation of the probe system 10, for example, the heat generated by heating of the chuck 131. Alternatively, the protective cover 50A may be at least partially made of an electromagnetic shielding material, such as tin foil, thereby isolating signal interference.

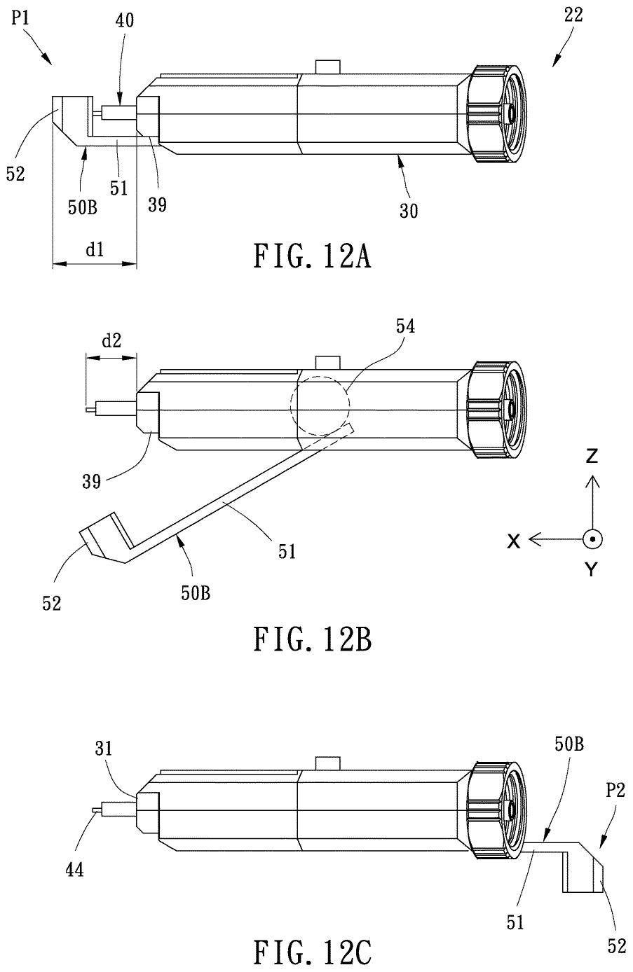

In the first preferred embodiment described above, the linearly slidable protective cover 50A requires only a short switching distance between the protection position P1 and the non-protection position P2, and does not occupy additional space, thereby avoiding interference with other components of the radio frequency probe device 21 or other components of the probe system 10. However, the present invention is not limited to a slidable protective cover. For example, the protective cover may be rotatably disposed on the main body, as in the protective covers 50B, 50C, and 50D provided in the second to fourth preferred embodiments of the present invention. When switching between the protection position P1 and the non-protection position P2, the protective covers 50B, 50C, and 50D rotate relative to the main body 30. More specifically, one end of the extension portion 51 of the protective covers 50B, 50C, and 50D is connected to the main body 30 via a pivot 54 (schematically shown in FIG. 12B). The pivot 54 is located between the front side and the rear side of the main body 30, such that the extension portion 51 may rotate about the pivot 54 to drive the protective portion 52 to rotate toward the probe tip unit 44 to reach the protection position P1, thereby shielding at least one side of the probe tip unit 44. Alternatively, the extension portion 51 may rotate in an opposite direction to reach the non-protection position P2, thereby moving the protective portion 52 away from the probe tip unit 44.

Referring to FIGS. 12A to 12C, in the radio frequency probe device 22 provided in accordance with the second preferred embodiment, the protective cover 50B is rotatably disposed on the main body 30 about a rotation axis (not shown) extending along the Y-axis. When the protective cover 50B is located at the protection position P1, the extension portion 51 extends along a protective cover mounting surface 39 located at a bottom side of the main body 30 and protrudes from the front side 31 of the main body 30. At this time, a protruding distance d1 by which the protective cover 50B extends from the front side 31 of the main body 30 is greater than a protruding distance d2 by which the probe 40 extends from the front side 31 of the main body 30. The protective portion 52 of the protective cover 50B is located around the probe tip unit 44 of the probe 40 and is capable of blocking external forces approaching the probe tip unit 44 from various directions, thereby achieving an effective probe tip protection effect. When the protective cover 50B is located at the protection position P1, the protective cover 50B shields the protective cover mounting surface 39. The term “shield” as used herein means that the protective cover may partially shield the protective cover mounting surface 39 and does not require complete coverage. When the protective cover 50B rotates away from the protection position P1, the protective cover 50B moves in a direction in which the protective cover mounting surface 39 faces, thereby moving away from the probe tip unit 44. In this embodiment, the protective cover mounting surface 39 faces downward, and the protective cover 50B rotates downwardly away from the protection position P1. In this embodiment, the non-protection position P2 of the protective cover 50B may be as shown in FIG. 12C, where the protective cover 50B has rotated 180 degrees relative to the protection position P1. The extension portion 51 still extends along the protective cover mounting surface 39 but now extends backwardly, such that the protective portion 52 is located behind the main body 30. Such a configuration prevents the protective cover 50B from occupying excessive space at the non-protection position P2 and avoids interference with other components. However, the non-protection position P2 of the protective cover 50B is not limited thereto.

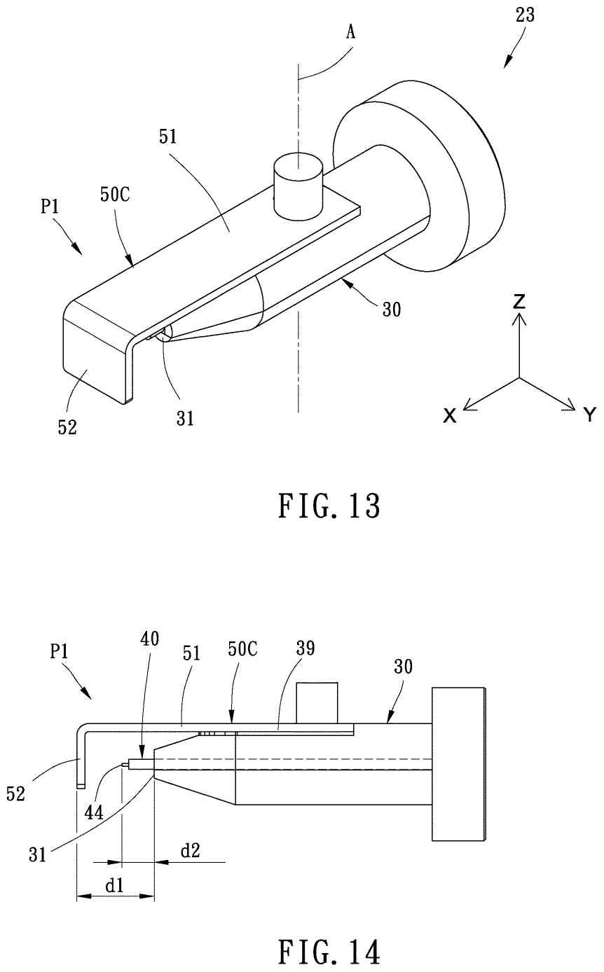

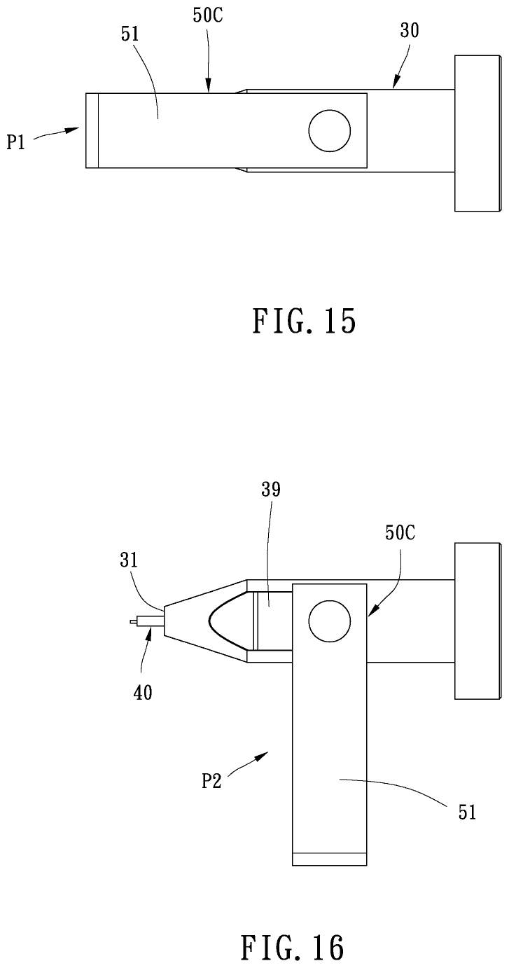

Referring to FIGS. 13 to 16, in the radio frequency probe device 23 provided in accordance with the third preferred embodiment, the protective cover 50C is rotatably disposed on the main body 30 about a rotation axis A extending along the Z-axis. When the protective cover 50C is located at the protection position P1, the extension portion 51 extends along a protective cover mounting surface 39 located at a top side of the main body 30 and protrudes from the front side 31 of the main body 30. The protective portion 52 extends downwardly from the extension portion 51 and is located in front of the probe tip unit 44 of the probe 40. That is, a protruding distance d1 by which the protective cover 50C extends from the front side 31 of the main body 30 is greater than a protruding distance d2 by which the probe 40 extends from the front side 31 of the main body 30. Accordingly, the protective portion 52 is capable of blocking external forces approaching the front of the probe tip unit 44, thereby achieving a probe tip protection effect. The rotation axis A is perpendicular to the protective cover mounting surface 39. When the protective cover 50C rotates away from the protection position P1, the protective cover 50C rotates in a direction parallel to the protective cover mounting surface 39 and partially separates from the protective cover mounting surface 39, such that the protective portion 52 moves away from the vicinity of the probe tip unit 44. In this embodiment, the non-protection position P2 of the protective cover 50C may be as shown in FIG. 16, where the protective cover 50C has rotated 90 degrees relative to the protection position P1 to avoid interference with other components. However, the non-protection position P2 of the protective cover 50C is not limited thereto.

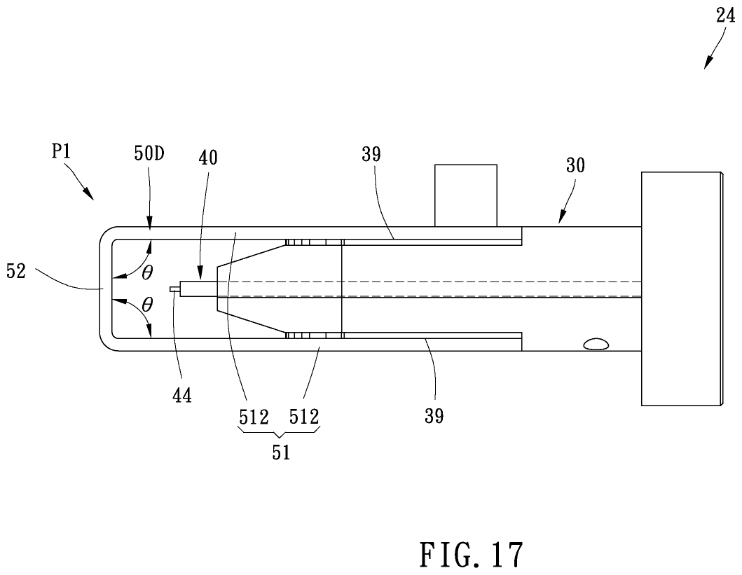

Referring to FIG. 17, in the radio frequency probe device 24 provided in accordance with the fourth preferred embodiment, the rotational mechanism of the protective cover 50D is similar to that of the protective cover 50C in the third preferred embodiment. The difference lies in that the extension portion 51 of the protective cover 50D comprises two parallel plate members 512, and the protective portion 52 is connected between the two plate members 512, such that an included angle θ is also formed between the protective portion 52 and each of the two plate members 512 of the extension portion 51. When the protective cover 50D is located at the protection position P1, the two plate members 512 respectively extend along two protective cover mounting surfaces 39 of the main body 30 and protrude from the front side 31 of the main body 30. The protective portion 52 is located in front of the probe tip unit 44 of the probe 40 to provide a probe tip protection effect.

The probe system 10 may also be applied to testing optical characteristics of a device under test. For example, the probe system 10 may be used to test an optoelectronic device under test (such as a silicon photonics chip), which comprises at least one optical test interface. The probe system 10 is connected to an optical probe device 25 through an optical measurement module. An optical coupling surface 44A of the optical probe device 25 is used to achieve optical coupling with the optical test interface, thereby performing optical signal transmission or power measurement on the optoelectronic device under test.

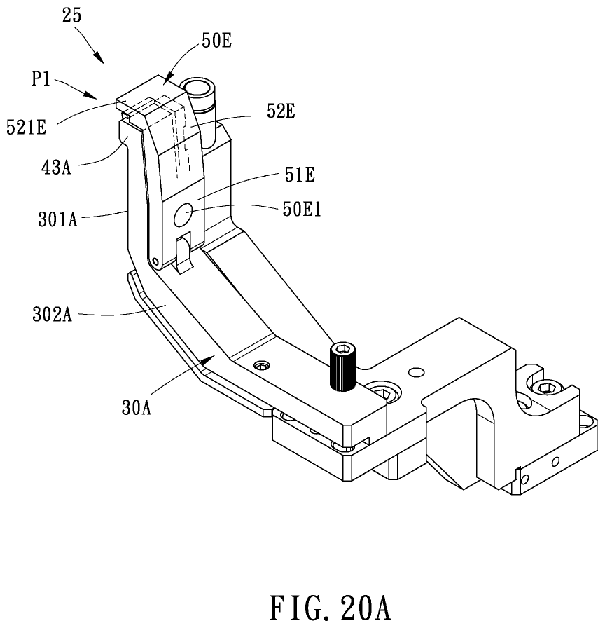

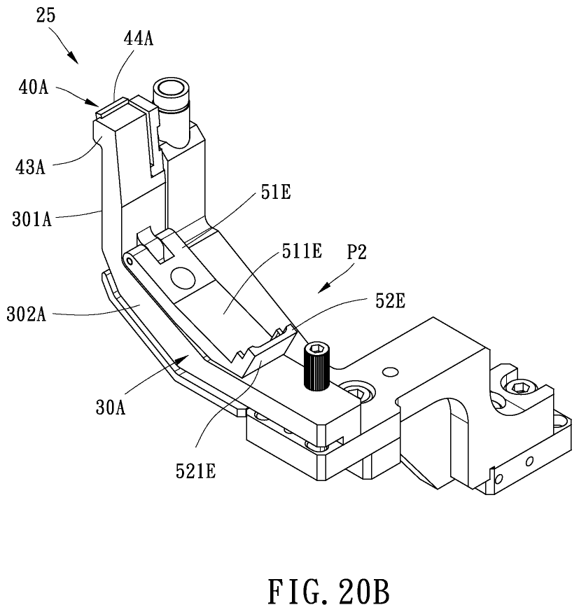

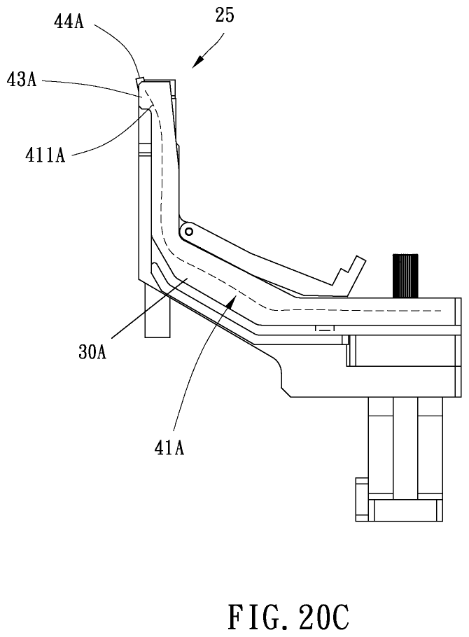

Referring to FIGS. 20A to 20C, in a fifth preferred embodiment, the probe device is an optical probe device 25, which comprises a main body 30A, a probe 40A disposed on the main body 30A, and a protective cover 50E. Correspondingly, the probe 40A is an optical probe. In this embodiment, the probe 40A is configured as a fiber array. The probe 40A comprises at least one optical fiber ribbon 41A and a support portion 43A. In this embodiment, the support portion 43A is a fiber mount extending from a front side of the main body 30A. Preferably, the support portion 43A and the main body 30A may be integrally formed as a single component. As shown in FIG. 20C, the optical fiber ribbon 41A is disposed in the main body 30A and extends to the support portion 43A. Specifically, the optical fiber ribbon 41A comprises a plurality of optical fibers 411A arranged in parallel. The optical fibers 411A are disposed within the support portion 43A in a parallel arrangement and, together with the support portion 43A, form a fiber array unit (FAU). By structurally integrating and positioning the plurality of optical fibers 411A arranged in parallel by means of the support portion 43A, ends of the optical fibers 411A protruding from the support portion 43A can stably and collectively form an optical coupling surface 44A, so as to correspond to a plurality of optical paths for parallel testing. It should be noted that FIG. 20C is a side view of the optical probe device 25. Due to the viewing angle, the optical fibers 411A appear as a single line in FIG. 20C; however, in actual structure, the optical fibers 411A comprise a plurality of optical fibers arranged in parallel.

In other embodiments, the probe 40A may be configured as a single-channel optical probe having a package tube with a coaxial-like structure for enclosing at least one optical fiber 411A. The optical fiber 411A is disposed in the main body 30A, extends to the support portion 43A, and is fixed thereto. The optical fiber 411A further protrudes outward from an end of the support portion 43A to form an optical coupling surface 44A, which serves as the probe end of the probe 40A.

Referring to FIGS. 20A and 20B, the protective cover 50E in this embodiment comprises an extension portion 51E and a protective portion 52E, wherein the protective portion 52E is located at one end of the extension portion 51E. Preferably, the protective portion 52E further comprises at least one guard plate 521E protruding from a surface 511E of the extension portion 51E facing toward the support portion 43A, such that an included angle is formed between the protective portion 52E and the extension portion 51E. The arrangement of the guard plate 521E corresponds to a shape of the support portion 43A. For example, in this embodiment, the support portion 43A has a block-like structure, and the protective portion 52E is formed as a guard plate 521E protruding from the surface 511E of the extension portion 51E. When the protective cover 50E is at the protection position P1, a space between the guard plate 521E and the extension portion 51E accommodates the support portion 43A, thereby shielding at least one side of the optical coupling surface 44A to achieve protection of the optical coupling surface 44A at an end of the optical fiber 411A. In other embodiments, the protective portion 52E may include three guard plates 521E that together define a U-shaped accommodating space corresponding to an end of the support portion 43A. Accordingly, when the protective cover 50E is at the protection position P1, the support portion 43A and the optical coupling surface 44A located at the end thereof are accommodated between the guard plates 521E, such that the protective portion 52E shields the end of the support portion 43A and both lateral sides thereof, thereby fully protecting the optical coupling surface 44A at the end of the optical fiber 411A.

In this embodiment, the protective cover 50E is pivotally connected to the main body 30A such that the protective cover 50E is rotatable relative to the main body 30A to switch between the protection position P1 and the non-protection position P2. Preferably, the main body 30A further comprises a first arm 301A and a second arm 302A connected to each other, wherein an included angle is formed between the first arm 301A and the second arm 302A (for example, in a substantially L-shaped configuration). In this embodiment, the first arm 301A extends, for example, in a vertical direction to be connected to the support portion 43A, and the second arm 302A extends, for example, in a horizontal direction to be connected to components of the optical probe mechanism. It should be noted that, in this embodiment, the first arm 301A, the second arm 302A, and the support portion 43A are integrally formed as a single component. In other embodiments, the first arm 301A, the second arm 302A, and the support portion 43A may be separate components connected to each other by fastening, bonding, welding, or fitting, and the present invention is not limited thereto. In this embodiment, the protective cover 50E is pivotally connected at a junction of the first arm 301A and the second arm 302A, such that the protective cover 50E is rotatable within a space defined by the first arm 301A and the second arm 302A, thereby effectively utilizing a space of the main body 30A and avoiding interference with testing operations.

In this embodiment, a specific portion of the protective cover 50E, for example (but not limited to) the extension portion 51E, is provided with a magnetic element 50E1. The magnetic element 50E1 may be, for example (but not limited to), a magnet, and the first arm 301A and the second arm 302A are respectively made of a material capable of being magnetically attracted. Accordingly, when the protective cover 50E is rotated to the protection position P1, the magnetic element 50E1 on the extension portion 51E magnetically attracts the first arm 301A, thereby fixing the protective cover 50E at the protection position P1. Similarly, when the protective cover 50E is rotated to the non-protection position P2, the magnetic element 50E1 on the extension portion 51E magnetically attracts the second arm 302A, thereby fixing the protective cover 50E at the non-protection position P2. By means of such magnetic attraction, the protective cover 50E can be stably positioned at the protection position P1 and the non-protection position P2 with a simple structure. In another embodiment, the first arm 301A and the second arm 302A may respectively be provided with a first magnetic element and a second magnetic element (not shown), such as magnets, while the protective cover 50E (or at least the extension portion 51E thereof) is made of a material capable of being magnetically attracted. In this manner, the protective cover 50E can likewise be fixed at the protection position P1 or the non-protection position P2 by magnetic attraction.

From the foregoing description, it can be understood that the present invention also provides a probe end protection method for a probe device, comprising:
providing a main body 30, 30A disposed with a probe 40, 40A, wherein the probe 40, 40A comprises a support portion 43, 43A protruding outside the main body 30, 30A and extending from a front side of the main body 30, 30A, and a probe end disposed at an end of the support portion 43, 43A. The probe is one of a radio frequency probe and an optical probe;
disposing a protective cover 50A-50E on the main body 30, 30A such that the protective cover 50A-50E is switchable relative to the main body 30, 30A between a protection position P1 and a non-protection position P2 while remaining connected to the main body 30, 30A, and selectively positionable at either the protection position P1 or the non-protection position P2;
wherein, when the protective cover 50A-50E is moved to the protection position P1, i.e., when the probe is not in use, a protective portion 52, 52E of the protective cover 50A-50E shields at least one side of the probe end, thereby protecting the probe end; and
when the protective cover 50A-50E is moved to the non-protection position P2, i.e., when the probe is in a state of use, the protective cover 50A-50E moves away from the probe end, such that the probe end of the radio frequency probe can electrically contact the test interface of the device under test 11, and the optical probe can optically couple with the test interface.

Accordingly, the above method not only provides effective protection for the probe end of the radio frequency probe or the optical probe, but also improves operational convenience and safety of the probe device, and further enhances testing efficiency.

The invention being thus described, it will be obvious that the same may be varied in many ways. Such variations are not to be regarded as a departure from the scope of the invention, and all such modifications as would be obvious to one skilled in the art are intended to be included within the scope of the following claims.

What is claimed is:

1. A probe device for use in a probe system to test a device under test, the device under test comprising at least one test interface, the probe device comprising:
a main body;
a probe disposed on the main body and comprising a support portion protruding outside the main body and extending from a front side of the main body, and a probe end disposed at an end of the support portion, wherein the probe is one of a radio frequency probe and an optical probe, the radio frequency probe is configured to electrically contact the test interface, and the optical probe is configured to optically couple with the test interface; and
a protective cover disposed on the main body and switchable relative to the main body between a protection position and a non-protection position while remaining connected to the main body, and selectively positionable at either the protection position or the non-protection position;
wherein, when the protective cover is at the protection position, a protective portion of the protective cover shields at least one side of the probe end; and
wherein, when the protective cover is at the non-protection position, the protective cover is spaced away from the probe end.

2. The probe device as claimed in claim 1, wherein, when the probe is the radio frequency probe, the support portion is a probe beam, the probe end is a probe tip unit fixed to the probe beam, and the probe tip unit extends from the probe beam away from the front side of the main body.

3. The probe device as claimed in claim 2, wherein the probe further comprises a coaxial line disposed in the main body; the coaxial line comprises a signal transmission path and a ground potential transmission path surrounding the signal transmission path; the coaxial line protrudes from the front side of the main body to form the probe beam; the probe tip unit comprises a signal probe tip electrically connected with the signal transmission path, and a ground probe tip electrically connected with the ground potential transmission path; the protective cover is disposed adjacent to the coaxial line.

4. The probe device as claimed in claim 2, wherein the protective cover is movable in a direction consistent with an extending direction of the probe beam.

5. The probe device as claimed in claim 1, wherein, when the protective cover is at the protection position, a distance by which the protective cover protrudes from the front side of the main body is greater than a distance by which the probe protrudes from the front side of the main body.

6. The probe device as claimed in claim 2, wherein the protective cover is slidably disposed on the main body so as to move between the protection position and the non-protection position.

7. The probe device as claimed in claim 6, wherein the main body comprises a rear side opposite to the front side, and two coaxial connecting terminals disposed on the rear side; the probe is electrically connected with the two coaxial connecting terminals; the main body further comprises a sliding groove into which the protective cover is slidably disposed; the sliding groove is located between the two coaxial connecting terminals; the main body gradually widens from the front side toward the rear side.

8. The probe device as claimed in claim 1, wherein the front side of the main body is provided with at least one receiving recess; when the protective cover is at the non-protection position, the protective portion is accommodated in the at least one receiving recess.

9. The probe device as claimed in claim 2, wherein the protective cover comprises an extension portion, the protective portion is located at one end of the extension portion, and an included angle is formed between the protective portion and the extension portion.

10. The probe device as claimed in claim 9, wherein the protective portion is located on opposite two sides of the extension portion to form a passage for accommodating the probe tip unit of the probe, and when the protective cover is at the protection position, the probe tip unit is located within the passage.

11. The probe device as claimed in claim 10, wherein the extension portion comprises an upper surface; the probe is located above the upper surface of the extension portion; the protective portion comprises two guard plates protruding from the upper surface; the passage is formed between the two guard plates.

12. The probe device as claimed in claim 10, wherein the main body comprises a sliding groove into which the extension portion is slidably disposed; the protective portion extends from the extension portion toward the probe tip unit of the probe to form the passage through which the probe passes.

13. The probe device as claimed in claim 1, wherein the main body comprises an elongated slot, and the probe device further comprises a positioning unit disposed in the elongated slot and operable by a user to switch between a positioned state and a non-positioned state; the positioning unit is connected with the protective cover; when the positioning unit is in the non-positioned state, the positioning unit is slidable along the elongated slot to thereby drive the protective cover to slide, and when the positioning unit is in the positioned state, the positioning unit is restricted and positioned within the elongated slot to thereby position the protective cover.

14. The probe device as claimed in claim 1, wherein the protective cover is rotatably disposed on the main body; when the protective cover switches between the protection position and the non-protection position, the protective cover rotates relative to the main body.

15. The probe device as claimed in claim 14, wherein the main body comprises a protective cover mounting surface; when the protective cover rotates away from the protection position, the protective cover moves in a direction in which the protective cover mounting surface faces; or when the protective cover switches between the protection position and the non-protection position, the protective cover rotates about a rotation axis perpendicular to the protective cover mounting surface.

16. The probe device as claimed in claim 1, wherein, when the probe is the optical probe, the probe comprises at least one optical fiber, the at least one optical fiber is disposed in the main body and extends and is fixed to the support portion, and the probe end is an optical coupling surface formed by the at least one optical fiber protruding outward from an end of the support portion.

17. The probe device as claimed in claim 16, wherein the protective cover comprises an extension portion, and the protective portion comprises at least one guard plate protruding from a surface of the extension portion facing toward the support portion, and the at least one guard plate is configured to correspond to a shape of the support portion.

18. The probe device as claimed in claim 16, wherein the main body comprises a first arm and a second arm, the support portion is connected to the first arm, and the protective cover is pivotally connected at a junction of the first arm and the second arm or at a position adjacent to the junction; the protective cover, the first arm, and the second arm are configured such that the protective cover is selectively positionable at the protection position and the non-protection position by at least one magnetic element.

19. The probe device as claimed in claim 1, wherein, when the probe is the optical probe, the probe comprises an optical fiber ribbon; the optical fiber ribbon is disposed in the main body and comprises a plurality of optical fibers arranged in parallel; the plurality of optical fibers are disposed in the support portion; the plurality of optical fibers and the support portion collectively form a fiber array unit, and ends of the plurality of optical fibers collectively define an optical coupling surface.

20. A protection method for a probe end of a probe device, applied to the probe device used in a probe system to test a device under test, the device under test comprising at least one test interface, the protection method comprising:
providing a main body disposed with a probe comprising a support portion protruding outside the main body and extending from a front side of the main body, and a probe end disposed at an end of the support portion, wherein the probe is one of a radio frequency probe and an optical probe;
disposing a protective cover on the main body such that the protective cover is switchable relative to the main body between a protection position and a non-protection position while remaining connected to the main body, and selectively positionable at either the protection position or the non-protection position;
wherein, when the protective cover is moved to the protection position, a protective portion of the protective cover shields at least one side of the probe end to protect the probe end; and
when the protective cover is moved to the non-protection position, the protective cover moves away from the probe end, thereby enabling the probe end of the radio frequency probe to electrically contact the test interface of the device under test, or enabling the probe end of the optical probe to optically couple with the test interface.

21. A probe system for testing a device under test formed on a substrate, the probe system comprising:
a probe device as claimed in claim 1;
a probing station comprising a chuck for supporting the substrate; and
a signal measurement module electrically connected with the probe of the probe device for transmitting signals to the device under test or receiving signals from the device under test through the probe device.

22. A testing method for testing a device under test, the testing method comprising:
providing a probe system as claimed in claim 21;
positioning the probe device at a position aiming at the device under test; and
bringing the probe end of the radio frequency probe of the probe device into contact with the device under test and detecting an electric characteristic of the device under test; or
bringing the probe end of the optical probe of the probe device into optical coupling with the device under test and detecting an optical characteristic of the device under test.

23. A tested device, which is a device tested by the testing method as claimed in claim 22.
